(19) United States
(12) Patent Application Publication
(10) Pub. No.: US 2013/0233374 A1
(43) Pub. Date: Sep. 12, 2013

(54) MONOLITHICALLY INTEGRATED SOLAR MODULES AND METHODS OF MANUFACTURE

(71) Applicant: GENERAL ELECTRIC COMPANY, Schenectady, NY (US)

(72) Inventors: Bastiaan Arie Korevaar, Schenectady, NY (US); James Neil Johnson, Scotia, NY (US); Holly Ann Blaydes, Burnt Hills, NY (US); James Edward Pickett, Niskayuna, NY (US); Thomas Miebach, Ballston Spa, NY (US)

(73) Assignee: GENERAL ELECTRIC COMPANY, SCHENECTADY, NY (US)

(21) Appl. No.: 13/866,132

(22) Filed: Apr. 19, 2013

Related U.S. Application Data
(62) Division of application No. 12/790,698, filed on May 28, 2010, now abandoned.

(51) Int. Cl. H01L 31/05; H01L 31/18

(52) U.S. Cl. CPC H01L 31/0516; H01L 31/1828
USPC 136/249; 438/73

(57) ABSTRACT

A monolithically integrated cadmium telluride (CdTe) photovoltaic (PV) module includes a first electrically conductive layer and an insulating layer. The first electrically conductive layer is disposed below the insulating layer. The PV module further includes a back contact metal layer and a CdTe absorber layer. The back contact metal layer is disposed between the insulating layer and the CdTe absorber layer. The PV module further includes a window layer and a second electrically conductive layer. The window layer is disposed between the CdTe absorber layer and the second electrically conductive layer. At least one first trench extends through the back contact metal layer, at least one second trench extends through the absorber and window layers, and at least one third trench extends through the second electrically conductive layer. A method for monolithically integrating CdTe PV cells is also provided.

### CROSS REFERENCE TO RELATED APPLICATIONS

This application is a division of U.S. patent application Ser. No. 12/790,698, Bastiaan Arie Korevaar et al., entitled “Monolithically integrated solar modules and methods of manufacture,” which is a continuation-in-part of U.S. patent application Ser. No. 12/138,001, filed Jun. 12, 2008 and entitled “Insulating coating, methods of manufacture thereof and articles comprising the same,” both of which patent applications are incorporated by reference herein in their entirety.

### BACKGROUND

The invention relates generally to photovoltaic cells and, more particularly, to monolithically integrated cadmium telluride (CdTe) modules.

PV (or solar) cells are used for converting solar energy into electrical energy. Typically, in its basic form, a PV cell includes a semiconductor junction made of two or three layers that are disposed on a substrate layer, and two contacts (electrically conductive layers) for passing electrical energy in the form of electrical current to an external circuit. Moreover, additional layers are often employed to enhance the conversion efficiency of the PV device.

There are a variety of candidate material systems for PV cells, each of which has certain advantages and disadvantages. CdTe is a prominent polycrystalline thin-film material, with a nearly ideal bandgap of about 1.45-1.5 electron volts. CdTe also has a very high absorptivity, and films of CdTe can be manufactured using low-cost techniques.

In order to form solar modules, PV cells must be electrically interconnected. The conventional interconnection approach involves connecting discrete cells together via shingling or metallic ribbons. In the conventional approach, interconnected cells do not maintain a common substrate.

Another interconnection technique is monolithic integration, in which PV cells are electrically interconnected as part of the cell fabrication process. Monolithic integration typically is implemented for thin film PV modules, where PV layers are deposited over large area substrates. Thin film PV modules are implemented by dividing the module into individual cells that are series connected to provide a high voltage output. Scribe and pattern steps are often used to divide the large area into electrically interconnected cells while maintaining a common substrate. This approach is typically applied to solar cells that are deposited on glass.

Several approaches exist for implementing monolithic integration, and each approach has various advantages and disadvantages related to the fabrication sequence, required tools, and material interactions, among other factors.

One of the key challenges in thin film PV fabrication relates to the need to isolate the top contacts of neighboring cells, i.e., scribe through the top conducting outer layer without damaging the underlying layers. Three scribes are typically necessary to form a monolithic interconnect. The spacing between scribes should be wide enough to overcome the possibility of unwanted electrical connections. However, the total area occupied by the scribes, plus any space between scribes, should ideally be as small as possible to maximize the absorbing area of the PV cell. Mechanical scribing is often not practical for flexible substrates, and laser scribing can be challenging, if the underlying layers are more highly absorbing than the overlying layer.

FIG. 1 illustrates an example, conventional monolithic PV cell interconnect process for a copper indium gallium diselenide (Cu(In, Ga)Se₂ or CIGS) cell. As shown, for example, in FIG. 1, the process begins by depositing a first conducting layer 60 on a substrate 62. For the illustrated process, the first conducting layer 60 is scribed using a linear cut 64 across the module. A semiconductor layer 66, such as a CIGS, layer is then deposited as depicted in FIG. 1. A second scribe 68 parallel to the first scribe 64 isolates the CIGS layer 66 into individual PV cells. A second conducting layer 70, for example a transparent conductive oxide (TCO) layer, is then deposited as also depicted in FIG. 1. The monolithic integration process is completed with a third scribe 72, which leaves the series connection 74, in which the TCO from the second conducting layer 70 connects the top of one PV cell 76 to the bottom of the next PV cell 78. The resulting monolithically integrated CIGS cells 76, 78 have what is termed a “substrate geometry.” Namely, the cells 76, 78 are disposed on an insulating substrate 62 (which is typically glass) and include a transparent upper contact formed from TCO layer 70.

Monolithic interconnection is typically limited in application to PV module fabrication on glass substrates due to the inherent difficulties in aligning the three scribes for cells grown on flexible substrates. However, in order to manufacture light-weight and robust CdTe solar modules, it would be desirable to use flexible substrates, such as metal or polymer webs.

Conventional CdTe PV cells are deposited in a “superstrate” geometry, as illustrated in FIG. 2. As shown in FIG. 2, the CdTe solar cell 80 is formed on a glass substrate 82. A transparent conductive layer 84, typically a TCO layer 84 is deposited on the glass substrate 82. Next, an optional high resistance transparent conductive oxide (HRT) layer 86 may be deposited on the TCO layer 84, and typically a CdS layer 88 is deposited on the HRT layer 86. A CdTe layer 90 is deposited on the CdS layer 88, and a back contact 92 is formed. In addition, an upper glass substrate 94 may be included to provide an inexpensive, environmental barrier.

However, conventional CdTe cells manufactured in superstrate geometries can have certain drawbacks. For example, it may not be possible to optimize the window layer because of the subsequent deposition of the absorber layer at high temperatures. Further, conventional CdTe cells deposited in superstrate geometries typically are formed on a glass substrate 82, which can add to the overall weight and detract from the robustness of the resulting PV module.

It would therefore be desirable to provide a method for manufacturing CdTe PV cells in a substrate geometry, such that flexible substrates, such as metal or polymer webs, can be employed. It would further be desirable to provide a method for monolithically integrating CdTe PV cells deposited in a substrate geometry, in order to reduce processing time and cost.

### BRIEF DESCRIPTION

One aspect of the present invention resides in a monolithically integrated cadmium telluride (CdTe) photovoltaic (PV) module comprising a first electrically conductive layer and an insulating layer. The first electrically conductive layer is disposed below the insulating layer. The CdTe PV module further includes a back contact metal layer and a CdTe absorber layer. The back contact metal layer is disposed between the insulating layer and the CdTe absorber layer. The CdTe PV module further includes a window layer and a second electrically conductive layer. The window layer is disposed between the CdTe absorber layer and the second electrically conductive layer. At least one first trench extends through the back contact metal layer. Each first trench separates the back contact metal layer for a respective CdTe PV cell from the back contact metal layer of a respective neighboring CdTe PV cell. At least one second trench extends through the absorber and window layers. Each second trench separates the absorber and window layers for a respective CdTe PV cell from the absorber and window layers of a respective neighboring CdTe PV cell. At least one third trench extends through the second electrically conductive layer. Each third trench separates the second electrically conductive layer for a respective CdTe PV cell from the second electrically conductive layers of a respective neighboring CdTe PV cell.

Another aspect of the present invention resides in a method for monolithically integrating CdTe PV cells. The monolithic integration method includes the steps of providing a first electrically conductive layer, depositing an insulating layer above the first electrically conductive layer, depositing a back contact metal layer above the insulating layer and forming at least one first trench extending through the back contact metal layer. Each first trench separates the back contact metal layer for a respective CdTe PV cell from the back contact metal layer of a respective neighboring CdTe PV cell.

The monolithic integration method further includes the steps of depositing a CdTe absorber layer at least partially above the back contact metal layer, depositing a window layer above the CdTe absorber layer and forming at least one second trench extending through the absorber and window layers. Each second trench separates the absorber and window layers for a respective CdTe PV cell from the absorber and window layers of a respective neighboring CdTe PV cell.

The monolithic integration method further includes the steps of depositing a second electrically conductive layer at least partially above the window layer and forming at least one third trench extending through the second electrically conductive layer. Each third trench separates the second electrically conductive layer for a respective CdTe PV cell from the second electrically conductive layer of a respective neighboring CdTe PV cell.

### DRAWINGS

These and other features, aspects, and advantages of the present invention will become better understood when the following detailed description is read with reference to the accompanying drawings in which like characters represent like parts throughout the drawings, wherein:

FIG. 1 illustrates an example, conventional monolithic PV cell interconnect process for CIGS;

FIG. 2. illustrates a conventional CdTe PV cell manufactured in a “superstrate” configuration;

FIG. 3 is a schematic cross-sectional diagram of an example CdTe stack manufactured in a “substrate” configuration;

FIG. 4 illustrates the first three steps for an example, monolithic integration process for CdTe PV cells manufactured in a “substrate” configuration, in accordance with embodiments of the present invention;

FIG. 5 illustrates the next three steps for the example process shown in FIG. 4;

FIG. 6 is a schematic cross-sectional diagram of another example CdTe stack with a semiconductor contact layer that is manufactured in a “substrate” configuration;

FIG. 7 is a schematic cross-sectional diagram of an example monolithically integrated CdTe module manufactured in a “substrate” configuration and with the semiconductor contact layer of FIG. 6;

FIG. 8 is a schematic cross-sectional diagram of another example CdTe stack with an HRT layer and manufactured in a “substrate” configuration; and

FIG. 9 is a schematic cross-sectional diagram of an example monolithically integrated CdTe module manufactured in a “substrate” configuration and with the HRT layer of FIG. 8.

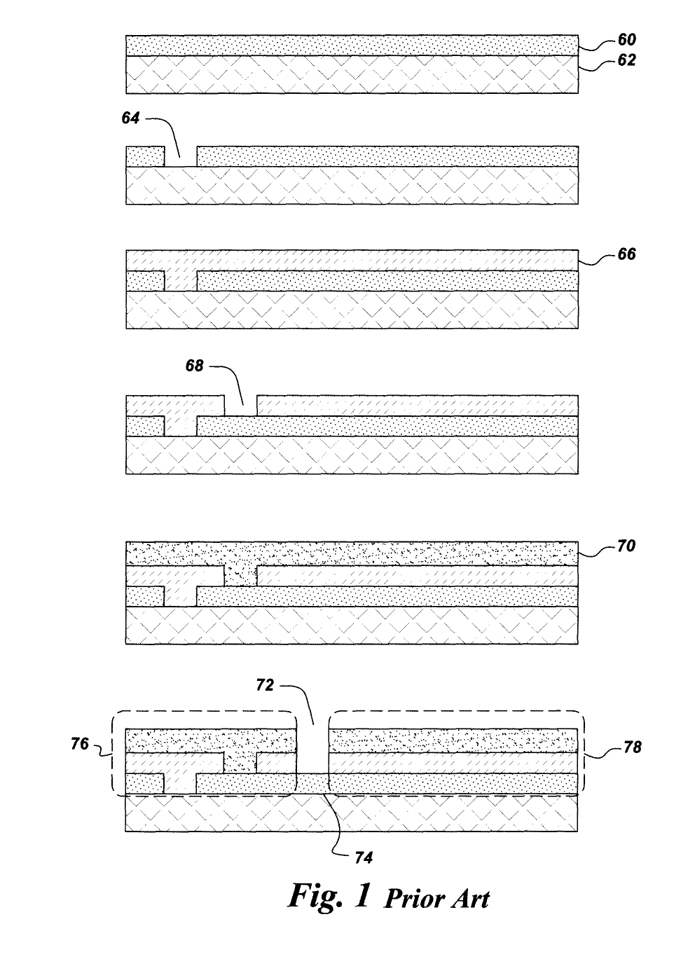

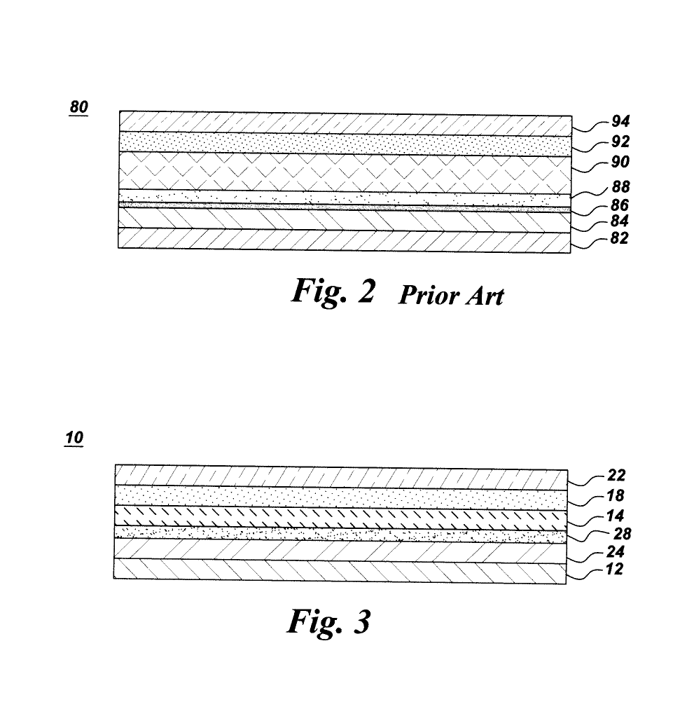

### DETAILED DESCRIPTION

A method is provided to monolithically integrate CdTe PV cells manufactured in a “substrate” configuration. The monolithically interconnected module 100 may be formulated from a single device 10, such as that depicted in FIG. 3. The configuration shown in FIG. 3 includes a first electrically conductive layer 12, a CdTe absorber layer 14, a window layer 18 and a second electrically conductive layer 22. For the example arrangement shown in FIG. 3, the first electrically conductive layer 12 is disposed below the CdTe absorber layer 14, and the window layer 18 is disposed below the second electrically conductive layer 22.

For particular arrangements, the CdTe absorber layer 14 comprises a p-type semiconductor layer 14. Non-limiting example materials for the p-type semiconductor layer 14 include zinc telluride (ZnTe), CdTe, magnesium telluride (MgTe), manganese telluride (MnTe), beryllium telluride (BeTe) mercury telluride (HgTe), copper telluride (CuₓTe), and combinations thereof. These materials should also be understood to include the alloys thereof. For example, CdTe can be alloyed with zinc, magnesium, manganese, and/or sulfur to form cadmium zinc telluride, cadmium copper telluride, cadmium manganese telluride, cadmium magnesium telluride and combinations thereof. These materials may be actively doped to be p-type. Suitable dopants vary based on the semiconductor material. For CdTe, suitable p-type dopants include, without limitation, copper, gold, nitrogen, phosphorus, antimony, arsenic, silver, bismuth, and sodium.

For these arrangements, the window layer 18 comprises an n-type semiconductor layer. Non-limiting example materials for the n-type semiconductor layer 18 include cadmium sulfide (CdS), indium (III) sulfide (In₂S₃), zinc sulfide (ZnS), zinc telluride (ZnTe), zinc selenide (ZnSe), cadmium selenide (CdSe), oxygenated cadmium sulfide, copper oxide (Cu₂O), amorphous or micro-crystalline silicon, and Zn(O,H) and combinations thereof. According to a particular embodiment, the n-type semiconductor layer 18 comprises CdS and has a thickness in a range of about 50-100 nm. The atomic percent of cadmium in the cadmium sulfide, for certain configurations, is in a range of about 45-55 atomic percent, and more particularly, in a range of about 48-52 atomic percent.

For these arrangements, the p-type semiconductor layer 14 and the n-type semiconductor layer 18 form a PN junction, which when exposed to appropriate illumination, generates a photovoltaic current, which is collected by the electrically conductive layers 12, 22, which are in electrical communication with appropriate layers of the device.

For certain arrangements, the second electrically conductive layer 22 comprises a transparent conductive oxide (TCO). Non-limiting examples of transparent conductive oxides include indium tin oxide (ITO), fluorine-doped tin oxide (SnO:F) or FTO, indium-doped cadmium-oxide, cadmium stannate (Cd₂SnO₄) or CTO, and doped zinc oxide (ZnO), such as aluminum-doped zinc-oxide (ZnO:Al) or AZO, indium-zinc oxide (IZO), and zinc tin oxide (ZnSnOₓ), and combinations thereof. Depending on the specific TCO employed (and on its sheet resistance), the thickness of the TCO layer 22 may be in the range of about 50-500 nm and, more particularly, 100-200 nm.

For particular configurations, the first electrically conductive layer 12 comprises a metal substrate, and non-limiting materials for the metal substrate 12 include nickel, nickel alloys, copper and copper alloys, and molybdenum and molybdenum alloys. In order to perform monolithic integration on the semiconductor stack shown in FIG. 3, the first electrically conductive layer 12 must be separated from the CdTe absorber and window layers 14, 18 by one or more insulating layers. For the configuration shown in FIG. 3, the PV cell 10 further includes an insulating layer 24 disposed between the first electrically conductive layer 12 and the CdTe absorber layer 14.

For particular embodiments, the insulating layer 24 comprises silicon, titanium, tin, lead, or germanium. Non-limiting example materials for the insulating layer 24 include single crystal or polycrystalline insulators formed using materials, such as silicon dioxide (SiO₂), titanium dioxide (TiO₂) and silicon oxycarbide (SiOC). According to more particular embodiments, the insulating layer has the formula SiOₓC_{y}H_{z}, and x, y and z each have values in a range of about 0.001-2 respectively, more particularly about 0.01 to about 0.9, and still more specifically about 0.1 to about 0.5. In one non-limiting example, x is about 1.8, y is about 0.4 and z is about 0.07. When formed from these materials, the insulating layer 24 retains its insulating properties at a temperature greater than or equal to about 300° C., more particularly at temperatures greater than or equal to about 400° C., and still more particularly, at temperatures greater than or equal to about 500° C.

In one embodiment, the insulating layer 24 is substantially amorphous. The insulating layer 24 can have an amorphous content of about 10 to about 90 weight percent (wt %), based upon the total weight of the insulating layer. For particular arrangements, the insulating layer 24 is completely amorphous.

For particular configurations, the insulating layer 24 has a thickness in a range of about 1-100 μm, more particularly about 1-50 μm, and still more particularly about 2-20 μm. In one non-limiting example, the insulating layer 24 has a thickness of about 5 μm.

Beneficially, the presence of the insulating layer 24 electrically isolates cells to facilitate monolithic integration of the PV cells 10 into a solar module (such as 100). In addition, the insulating layer 24 may act as a diffusion barrier to prevent diffusion of the metal (for example, nickel) from the contact 12 into the p-type material 14.

The configuration shown in FIG. 3 further includes a metal layer 28 disposed between the insulating layer 24 and the CdTe absorber layer 14. The metal layer 28 may comprise molybdenum, aluminum, chromium, gold, tungsten, tantalum, titanium, nickel, alloys thereof, or a combination/stack thereof. In one non-limiting example, the metal layer 28 comprises molybdenum or an alloy thereof. For this configuration, the metal layer 28 is used to make an ohmic contact with the CdTe absorber layer 14.

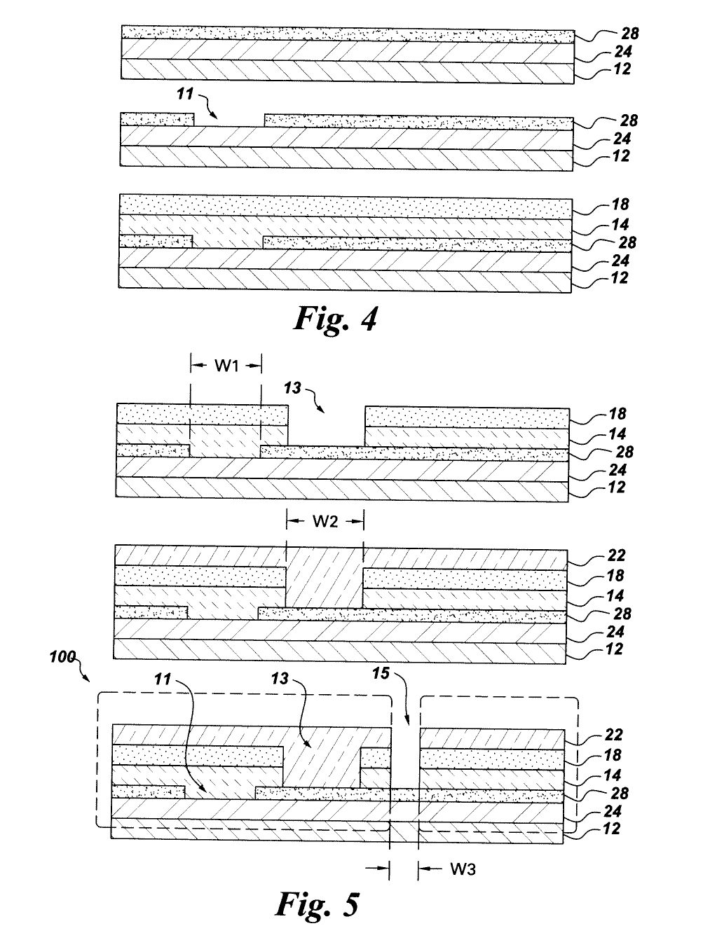

A monolithically integrated cadmium telluride (CdTe) photovoltaic (PV) module 100 embodiment of the invention is described with reference to FIGS. 4-9, and a monolithically integrated CdTe PV module 100 manufactured in a “substrate” geometry is shown in the lower most portion of FIG. 5. As shown, for example in FIG. 5, the monolithically integrated CdTe PV module 100 includes a first electrically conductive layer 12 and an insulating layer 24. The first electrically conductive layer 12 and the insulating layer 24 are discussed above with reference to FIG. 3 in detail. As indicated, the first electrically conductive layer 12 is disposed below the insulating layer 24.

The monolithically integrated CdTe PV module 100 further includes a back contact metal layer 28 and a CdTe absorber layer 14. As indicated, the back contact metal layer 28 is disposed between the insulating layer 24 and the CdTe absorber layer 14. According to particular embodiment, the CdTe absorber layer 14 comprises a p-type CdTe layer 14 with a thickness in a range of about 1-10 μm, and more particularly, about 1-3 μm thick. The back contact metal layer 28 and the CdTe absorber layer 14 are discussed above with reference to FIG. 3 in detail.

As shown, for example in FIG. 5, the monolithically integrated CdTe PV module 100 further includes a window layer 18 and a second electrically conductive layer 22. For the illustrated arrangement, the window layer 18 is disposed between the CdTe absorber layer 14 and the second electrically conductive layer 22. The window layer 18 and the second electrically conductive layer 22 are discussed above with reference to FIG. 3 in detail.

For the example configuration shown in FIG. 4, at least one first trench 11 extends through the back contact metal layer 28. Each of the first trenches 11 separates the back contact metal layer 28 for a respective CdTe PV cell 10 (see, for example FIG. 3) from the back contact metal layer 28 of a respective neighboring CdTe PV cell 10. For particular embodiments the width W₁ (see FIG. 5) of the first trenches 11 is in a range of about 50-200 μm. For certain configurations, the width W₁ is selected to be at least two times the thickness of the absorber layer 14.

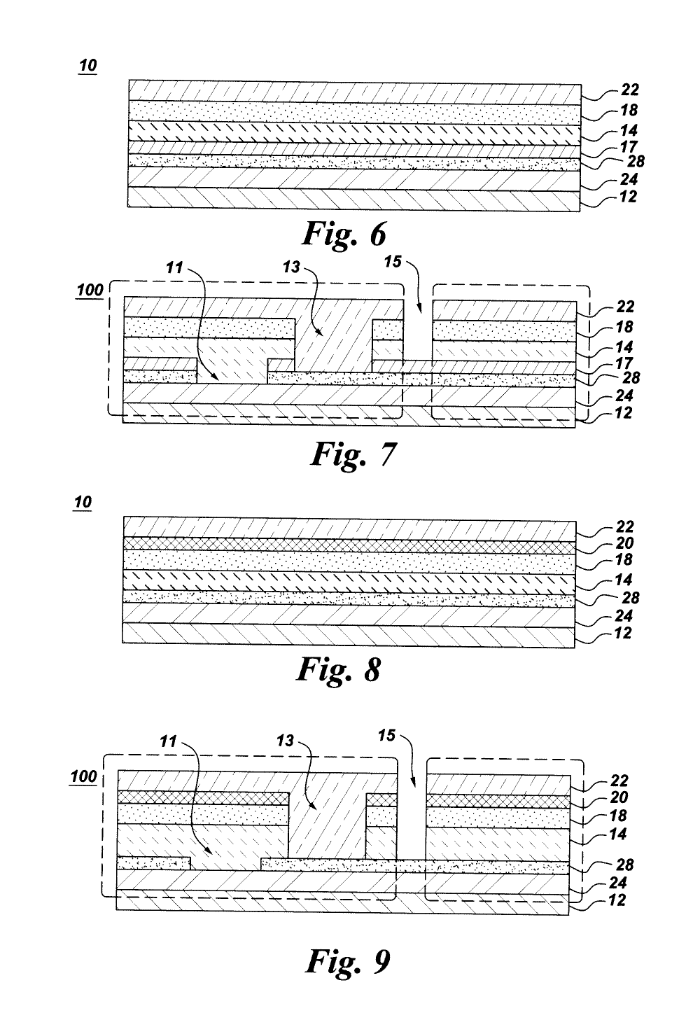

As shown, for example in FIG. 5, at least one second trench 13 extends through the absorber and window layers 14, 18. Each of the second trenches 13 separates the absorber and window layers 14, 18 for a respective CdTe PV cell 10 (see, for example FIG. 3) from the absorber and window layers 14, 18 of a respective neighboring CdTe PV cell 10. For particular embodiments, the width W₂ (see FIG. 6) of the second trenches 13 is in a range of about 50-200 μm. The width W₂ for the second trenches 13 may be selected to balance the increased area loss with the lower resistances associated with greater widths W₂.

At least one third trench 15 extends through the second electrically conductive layer 22. Each of the third trenches 15 separates the second electrically conductive layers 22 for a respective CdTe PV cell 10 (see, for example FIG. 3) from the second electrically conductive layers 22 of a respective neighboring CdTe PV cell 10. For the example configuration shown in FIG. 5, at least one third trench 15 extends through each of the absorber, window and second electrically conductive layers 14, 18, 22. Each of the third trenches 15 separates the absorber, window and second electrically conductive layers 14, 18, 22 for a respective CdTe PV cell 10 (see, for example FIG. 3) from the absorber, window and second electrically conductive layers 14, 18, 22 of a respective neighboring CdTe PV cell 10. For certain configurations the width W₃ is selected to be at least two times the thickness of the absorber layer 14.

For ease of illustration, only a single set of first, second and third trenches 11, 13, 15 is shown in FIGS. 4-9. However, PV module 100 may include a number of these trenches, such that a number of PV cells 10 are included in the module 100.

For the example configuration shown in FIGS. 4 and 5, each of the first trenches 11 is at least partially filled with CdTe, such that the first trenches 11 and the CdTe absorber layer 14 form an integral piece.

For the example configuration shown in FIG. 5, each of the second trenches 13 is at least partially filled with the material forming the second electrically conductive layer 22, such that the second trenches 13 and the second electrically conductive layer 22 form an integral piece. More generally, the second trenches 13 are at least partially filled with electrically conductive interconnecting material having a resistivity of less than about 10⁻³ Ohm-cm to provide an electrical current pathway from the second electrically conductive layer 22 of a CdTe PV cell 10 to the back contact metal layer 28 of a neighboring CdTe PV cell 10, as indicated for example in FIG. 5. The electrically conductive interconnecting material is patterned in such a way that it does not electrically connect the second electrically conductive layers 22 of CdTe PV cell 10. Suitable conductive polymers that may be used to provide the electrically conductive interconnecting material may include, without limitation, polyaniline, polyacetylene, poly-3,4-ethylene dioxy thiophene (PEDOT), poly-3,4-propylene dioxythiophene (PPropOT), polystyrene sulfonate (PSS), polyvinyl carbazole (PVK), organometallic precursors, dispersions or carbon nanotubes, etc.

Although not expressly shown, the first trenches 11 may be at least partially filled with an electrically resistive material. The electrically resistive material may have a resistivity greater than about 10 Ohm-cm, according to one aspect of the invention. Suitable example materials include, without limitation, negative photo-resist. For particular embodiments, one or more of the first, second and third trenches 11, 13, 15 are at least partially filled by a liquid dispense method such as, without limitation, ink-jet printing, screen printing, flexo printing, gravure printing, aerosol dispense, extrusion, syringe dispense, or any combination thereof.

Similarly, the third trenches 15 may be at least partially filled with an electrically resistive material (not expressly shown). The electrically resistive material may have a resistivity greater than about 10 ohm-cm, according to one aspect of the invention. Suitable example materials include, without limitation, SiO₂-like or Al₂O₃-like materials, which can be printed within the scribe.

FIGS. 6 and 7 illustrate additional optional features of monolithically integrated CdTe PV module 100. FIG. 6 is a schematic cross-sectional diagram of an example CdTe stack with a semiconductor contact layer 17 manufactured in a “substrate” configuration. FIG. 7 is a schematic cross-sectional diagram of an example monolithically integrated CdTe module manufactured in a “substrate” configuration and with the semiconductor contact layer 17 of FIG. 6. For the example configuration shown in FIG. 7, the monolithically integrated CdTe PV module 100 further includes a semiconductor back contact layer 17 disposed between the metal contact layer 28 and the CdTe absorber layer 14. As shown, for example, in FIG. 7, the first trench 11 also extends through the semiconductor back contact layer 17, such that each of the first trenches 11 separates the semiconductor back contact layer 17 and back contact metal layer 28 for a respective CdTe PV cell 10 from the semiconductor back contact layer 17 and back contact metal layer 28 of a respective neighboring CdTe PV cell 10. Similarly, for the illustrated embodiment, the second trench 13 also extends through the semiconductor back contact layer 17. For other example arrangements (not shown), the second trench 13 may terminate at and not extend through the semiconductor back contact layer 17. For particular embodiments, the semiconductor back contact layer 17 comprises a material selected from the group consisting of CuₓTe (where 1≦x≦2), As₂Te₃, Sb₂Te₃, ZnTe (optionally doped), HgTe, other tellurides, certain phosphides and nitrides, and p-type amorphous silicon, and combinations thereof and has a thickness in a range of about 20-100 nm. According to a particular embodiment, the semiconductor layer 17 comprises doped ZnTe (for example, ZnTe:Cu or ZnTe:N) and has a thickness in a range of about 50-100 nm.

FIGS. 8 and 9 illustrate additional optional features of monolithically integrated CdTe PV module 100. FIG. 8 is a schematic cross-sectional diagram of an example CdTe stack with an HRT layer 20 and manufactured in a “substrate” configuration, and FIG. 9 is a schematic cross-sectional diagram of an example monolithically integrated CdTe module manufactured in a “substrate” configuration and with the HRT layer 20 of FIG. 8. For the example configuration shown in FIG. 9, the monolithically integrated CdTe PV module 100 further includes a high resistance transparent conductive oxide (HRT) layer 20 disposed between the window layer 18 and the second electrically conductive layer 22. As shown, for example in FIG. 9, the second and third trenches 13, 15 extend through the HRT layer 22. According to a particular embodiment, the thickness of the HRT layer 20 is in a range of about 50 nm to about 100 nm. Beneficially, the HRT layer 20 serves as a buffer layer and can increase the efficiency of the PV cell 10. Non-limiting examples of suitable materials for HRT layer 20 include tin dioxide (SnO₂), ZTO (zinc stannate), zinc-doped tin oxide (SnO₂:Zn), zinc oxide (ZnO), indium oxide (In₂O₃), and combinations thereof.

A method for monolithically integrating cadmium telluride (CdTe) photovoltaic (PV) cells (10) manufactured in a “substrate” configuration is described with reference to the FIGS. 4 and 5. As shown for example in FIG. 4, the monolithic integration method includes providing a first electrically conductive layer 12. Example materials for the first electrically conductive layer 12 include nickel, copper, molybdenum, stainless steel, and alloys thereof. These materials may be deposited, for example by sputtering or evaporation. In addition, these materials may also be provided as a foil, such that flexible devices can be created. The metal foil may be up to a few mm in thickness. For the example process shown in FIG. 4, the monolithic integration method further includes depositing an insulating layer 24 above the first electrically conductive layer 12. For the illustrated examples, the insulating layer is deposited on the first electrically conductive layer 12. However, there may be intermediate layers as well. For particular arrangements, the insulating layer 24 may be deposited using a vapor phase deposition technique. Other example deposition techniques are described in U.S. patent application Ser. No. 12/138,001, “Insulating coating, methods of manufacture thereof and articles comprising the same,” which is incorporated herein in its entirety.

According to a particular embodiment, the insulating layer 24 is deposited in an expanding thermal plasma (ETP), and a metal organic precursor is used in the plasma. More particularly, the precursor is introduced into an ETP and a plasma stream produced by the ETP is disposed upon the surface of the first electrically conductive layer 12 (or an intermediate layer, not shown). For more particular embodiments, the metal-organic precursor comprises silicon, titanium, tin, lead, or germanium. Prior to applying the insulating layer 24, the first electrically conductive layer 12 can be etched if desired. For a particular process, the first electrically conductive layer 12 is first heated to the desired temperature following which the insulating layer is disposed thereon.

As explained in U.S. patent application Ser. No. 12/138,001, the use of ETP permits the rapid deposition of the insulating layer at relatively low temperatures, as compared to other techniques, such as sputtering or plasma enhanced chemical vapor deposition (PECVD). Under certain processing parameters, the insulating layer 24 can be deposited at a rate greater than or equal to about 0.1 μm per minute, and more particularly, at a rate greater than or equal to about 5 μm per minute, and still more particularly, at a rate greater than or equal to about 10 μm per minute, and even more particularly, at a rate greater than or equal to about 100 μm per minute. For particular arrangements, the insulating layer 24 is deposited at a rate of about 0.1-100 μm per minute and has a thickness of about 1-50 μm.

Similar to the discussion in U.S. patent application Ser. No. 12/138,001, ETP can be used to apply the insulating layer to large areas of the first electrically conductive layer 12 in a single operation. The insulating layer may comprise a single layer that is applied in a single step or in multiple steps if desired. Multiple sets of plasma generators may be used to increase deposition rate and/or the area of coverage. The ETP process may be carried out in a single deposition chamber or in multiple deposition chambers.

For the example process shown in FIG. 4, the monolithic integration method further includes depositing a back contact metal layer 28 above the insulating layer 24. Although for the illustrated examples, the metal back contact layer 28 is deposited on the insulating layer 24, there may also be one or more intermediate layers (not shown). The metal back contact layer 28 is typically deposited using sputtering or evaporation (for example, e-beam or molecular beam epitaxy). The example monolithic integration process shown in FIG. 4 further includes forming at least one first trench 11 extending through the back contact metal layer 28 and depositing a CdTe absorber layer 14 at least partially above the back contact metal layer 28. The first trenches 11 are discussed above and may be formed, for example, by performing a laser or mechanical scribe. As discussed above, the CdTe absorber layer 14 may comprise a p-type semiconductor layer 14 and example materials are listed above. A p-type CdTe absorber layer 14 is typically deposited by close space sublimation (CSS) or vapor phase transport. Alternatively, the p-type layer 14 may be deposited using sputtering, evaporation (for example, e-beam or molecular beam epitaxy), or chemical vapor deposition.

The example monolithic integration process shown in FIG. 4 further includes depositing a window layer 18 above the CdTe absorber layer (14). As discussed above, the window layer 18 may comprise an n-type semiconductor layer and example materials are listed above. An n-type window layer 18 is typically deposited by chemical bath (or vapor) deposition or electrochemical deposition. For example, chemical bath deposition may be used to deposit a CdS layer 18. Alternatively, an n-type window layer 18 may also be deposited using sputtering. Dopants may be introduced within semiconductor layers 14 and/or 18 using a variety of techniques, as discussed, for example, in commonly assigned U.S. patent application Ser. No. 12/415,267, “Layer for Thin Film Photovoltaics and a Solar Cell Made Therefrom,” which is incorporated by reference herein in its entirety.

As shown for example in FIG. 5, the monolithic integration method further includes forming at least one second trench 13 extending through the absorber and window layers 14, 18. The second trenches 13 are discussed above and may be formed, for example, by performing a laser or mechanical scribe. The example monolithic integration process shown in FIG. 5 further includes depositing a second electrically conductive layer 22 at least partially above the window layer 18 and forming at least one third trench 15 extending through each of the absorber, window and second electrically conductive layers 14, 18, 22. More generally, the monolithic integration process includes forming at least one third trench 15 extending through the second electrically conductive layer 22. The second electrically conductive layer (or back contact) 22 is typically deposited by sputtering a TCO layer 22. The third trenches 15 are discussed above and may be formed, for example, by performing a laser or mechanical scribe.

For the example process shown in FIG. 4, the first trenches 11 are formed prior to the deposition of the CdTe absorber layer 14. For this particular process sequence, the step of depositing the CdTe absorber layer 14 further comprises at least partially filling the first trenches 11 with CdTe, such that the first trenches 11 and the CdTe absorber layer 14 form an integral piece, as indicated in FIG. 4.

Similarly, for the example process shown in FIG. 5, the second trenches 13 are formed prior to the deposition of the second electrically conductive layer 22. For this particular process sequence, the step of depositing the second electrically conductive layer 22 further comprises at least partially filling the second trenches 13 with the material forming the second electrically conductive layer 22, such that the second trenches 13 and the second electrically conductive layer 22 form an integral piece, as indicated in FIG. 5.

For another process sequence (not expressly shown), the first, second and third trenches 11, 13, 15 are formed after the deposition of the second electrically conductive layer 22. For this process sequence, the three scribes may be performed in a single step, after the deposition of the various layers forming the PV device. For this particular process sequence, the monolithic integration method further includes at least partially filling the first trenches 11 with an electrically resistive material and at least partially filling the second trenches 13 with an electrically conductive material. For this embodiment, the scribes may be performed sequentially or simultaneously. Beneficially, performing the scribes simultaneously improves their alignment. The electrically conductive material may have a resistivity of less than about 10⁻³ Ohm-cm to provide an electrical current pathway from the second electrically conductive layer 22 of a CdTe PV cell 10 to the back contact metal layer 28 of a neighboring CdTe PV CELL 10. Example conductive polymers that may be used to provide the electrically conductive interconnecting material are listed above.

For another process sequence (not expressly shown), the monolithic integration method further includes at least partially filling the third trenches 15 with an electrically resistive material. Example electrically resistive materials are listed above.

Similarly, for another process sequence (not expressly shown), the first and second trenches 11, 13 are formed simultaneously prior to deposition of the second electrically conductive layer 22. For this particular process sequence, the monolithic integration method further includes at least partially filling the first trenches 11 with an electrically resistive material. Example electrically resistive materials are listed above.

For the example arrangement illustrated in FIGS. 6 and 7, the monolithic integration method further includes depositing a semiconductor back contact layer 17 after depositing the metal contact layer 28 and before depositing the CdTe absorber layer 14. Example materials for the semiconductor back contact layer 17 are listed above, and the semiconductor back contact layer 17 may be deposited, for example, by sputtering, co-evaporation, CSS, or electrochemical bath deposition. For this configuration, the first trenches 11 are formed after the deposition of the semiconductor back contact layer 17, such that the first trenches 11 also extend through the semiconductor back contact layer 17, as indicated in FIG. 7. The first trenches 11 for this configuration are described above with reference to FIG. 7.

For the example arrangement illustrated in FIGS. 8 and 9, the monolithic integration method further includes depositing a high resistance transparent conductive oxide (HRT) layer 20 after depositing the window layer 18 and before depositing the second electrically conductive layer 22. For the illustrated arrangement, the second and third trenches 13, 15 are formed after the deposition of the HRT layer 20, such that the second and third trenches 13, 15 extend through the HRT layer 20, as shown for example in FIG. 7. The optional HRT layer 20 is typically deposited using sputtering.

Beneficially, the above-described methodologies facilitate the monolithic integration of CdTe PV cells into solar modules on metallic substrates.

Although only certain features of the invention have been illustrated and described herein, many modifications and changes will occur to those skilled in the art. It is, therefore, to be understood that the appended claims are intended to cover all such modifications and changes as fall within the true spirit of the invention.

1. A monolithically integrated cadmium telluride (CdTe) photovoltaic (PV) module comprising:
a first electrically conductive layer;
an insulating layer, wherein the first electrically conductive layer is disposed below the insulating layer;
a back contact metal layer;
a CdTe absorber layer, wherein the back contact metal layer is disposed between the insulating layer and the CdTe absorber layer;
a window layer;
a second electrically conductive layer, wherein the window layer is disposed between the CdTe absorber layer and the second electrically conductive layer;
at least one first trench extending through the back contact metal layer, wherein each of the at least one first trenches separates the back contact metal layer for a respective CdTe PV cell from the back contact metal layer of a respective neighboring CdTe PV cell;
at least one second trench extending through the absorber and window layers, wherein each of the at least one second trenches separates the absorber and window layers for a respective CdTe PV cell from the absorber and window layers of a respective neighboring CdTe PV cell;
at least one third trench extending through the second electrically conductive layer, wherein each of the at least one third trenches separates the second electrically conductive layer for a respective CdTe PV cell from the second electrically conductive layers of a respective neighboring CdTe PV cell; and
a semiconductor back contact layer disposed between the metal contact layer and the CdTe absorber layer, wherein the at least one first trench also extends through the semiconductor back contact layer, such that each of the at least one first trenches separates the semiconductor back contact layer and back contact metal layer for a respective CdTe PV cell from the semiconductor back contact layer and back contact metal layer of a respective neighboring CdTe PV cell.

2. The monolithically integrated CdTe PV module of claim 1, wherein the at least one first trench is at least partially filled with CdTe, such that the at least one first trench and the CdTe absorber layer form an integral piece.

3. The monolithically integrated CdTe PV module of claim 1, wherein the at least one second trench is at least partially filled with the material forming the second electrically conductive layer, such that the at least one second trench and the second electrically conductive layer form an integral piece.

4. The monolithically integrated CdTe PV module of claim 1, wherein the at least one first trench is at least partially filled with an electrically resistive material.

5. The monolithically integrated CdTe PV module of claim 1, wherein the at least one third trench is at least partially filled with an electrically resistive material.

6. The monolithically integrated CdTe PV module of claim 1, wherein the window layer comprises a material selected from the group consisting of CdS, In₂S₃, In₂Se₃, ZnS, ZnTe, ZnSe, CdSe, oxygenated cadmium sulfide, Cu₂O, amorphous or micro-crystalline silicon, Zn(O,H) and combinations thereof.

7. The monolithically integrated CdTe PV module of claim 6, wherein the window layer comprises CdS.

8. The monolithically integrated CdTe PV module of claim 1, wherein the insulating layer comprises silicon, titanium, tin, lead, or germanium.

9. The monolithically integrated CdTe PV module of claim 8, wherein the insulating layer has the formula SiOₓC_{y}H_{z}, and wherein x, y and z each have values in a range of about 0.001-2 respectively.

10. The monolithically integrated CdTe PV module of claim 1, wherein the at least one third trench also extends through each of the absorber and window layers, and wherein each of the at least one third trenches separates the absorber, window and second electrically conductive layers for a respective CdTe PV cell from the absorber, window and second electrically conductive layers of a respective neighboring CdTe PV cell.

11. A monolithically integrated cadmium telluride (CdTe) photovoltaic (PV) module comprising:
a first electrically conductive layer;
an insulating layer, wherein the first electrically conductive layer is disposed below the insulating layer;
a back contact metal layer;
a CdTe absorber layer, wherein the back contact metal layer is disposed between the insulating layer and the CdTe absorber layer;
a window layer;
a second electrically conductive layer, wherein the window layer is disposed between the CdTe absorber layer and the second electrically conductive layer;
at least one first trench extending through the back contact metal layer, wherein each of the at least one first trenches separates the back contact metal layer for a respective CdTe PV cell from the back contact metal layer of a respective neighboring CdTe PV cell;
at least one second trench extending through the absorber and window layers, wherein each of the at least one second trenches separates the absorber and window layers for a respective CdTe PV cell from the absorber and window layers of a respective neighboring CdTe PV cell;
at least one third trench extending through the second electrically conductive layer, wherein each of the at least one third trenches separates the second electrically conductive layer for a respective CdTe PV cell from the second electrically conductive layers of a respective neighboring CdTe PV cell; and
a high resistance transparent conductive oxide (HRT) layer disposed between the window layer and the second electrically conductive layer, wherein the second and third trenches extend through the HRT layer.

12. A method for monolithically integrating cadmium telluride (CdTe) photovoltaic (PV) cells, the monolithic integration method comprising:
providing a first electrically conductive layer;
depositing an insulating layer above the first electrically conductive layer (12);
depositing a back contact metal layer above the insulating layer;
forming at least one first trench extending through the back contact metal layer, wherein each of the at least one first trenches separates the back contact metal layer for a respective CdTe PV cell from the back contact metal layer of a respective neighboring CdTe PV cell;
depositing a CdTe absorber layer at least partially above the back contact metal layer;
depositing a window layer above the CdTe absorber layer;
forming at least one second trench extending through the absorber and window layers, wherein each of the at least one second trenches separates the absorber and window layers for a respective CdTe PV cell from the absorber and window layers of a respective neighboring CdTe PV cell;
depositing a second electrically conductive layer at least partially above the window layer;
forming at least one third trench extending through the second electrically conductive layer, wherein each of the at least one third trenches separates the second electrically conductive layer for a respective CdTe PV cell from the second electrically conductive layer of a respective neighboring CdTe PV cell; and
depositing a semiconductor back contact layer after depositing the metal contact layer and before depositing the CdTe absorber layer, wherein the step of forming the at least one first trench is performed after the deposition of the semiconductor back contact layer, such that the at least one first trench also extends through the semiconductor back contact layer, such that each of the at least one first trenches separates the semiconductor back contact layer and back contact metal layer for a respective CdTe PV cell from the semiconductor back contact layer and back contact metal layer of a respective neighboring CdTe PV cell.

13. The monolithic integration method of claim 12, wherein the step of forming at least one first trench is performed prior to the step of depositing the CdTe absorber layer, and wherein the step of depositing the CdTe absorber layer further comprises at least partially filling the at least one first trench with CdTe, such that the at least one first trench and the CdTe absorber layer form an integral piece.

14. The monolithic integration method of claim 12, wherein the step of forming at least one second trench is performed prior to the step of depositing the second electrically conductive layer, and wherein the step of depositing the second electrically conductive layer further comprises at least partially filling the at least one second trench with the material forming the second electrically conductive layer, such that the at least one second trench and the second electrically conductive layer form an integral piece.

15. The monolithic integration method of claim 12, wherein the steps of forming the first, second and third trenches are performed after the step of depositing the second electrically conductive layer, the monolithic integration method further comprising:
at least partially filling the at least one first trench with an electrically resistive material; and
at least partially filling the at least one second trench with an electrically conductive material.

16. The monolithic integration method of claim 12, further comprising at least partially filling the at least one third trench with an electrically resistive material.

17. The monolithic integration method of claim 12, wherein the insulating layer is deposited in an expanding thermal plasma, wherein a metal organic precursor is used in the plasma, and wherein the metal-organic precursor comprises silicon, titanium, tin, lead, or germanium.

18. The monolithic integration method of claim 12, wherein the steps of forming the first and second trenches are performed simultaneously prior to the step of depositing the second electrically conductive layer, the monolithic integration method further comprising at least partially filling the at least one first trench with an electrically resistive material.

19. The monolithic integration method of claim 12, wherein the at least one third trench also extends through the absorber and window layers, and wherein each of the at least one third trenches separates the absorber, window and second electrically conductive layers for a respective CdTe PV cell from the absorber, window and second electrically conductive layers of a respective neighboring CdTe PV cell.

20. The monolithic integration method of claim 12, wherein the first, second and third trenches are formed simultaneously after the deposition of the second electrically conductive layer.

21. A method for monolithically integrating cadmium telluride (CdTe) photovoltaic (PV) cells, the monolithic integration method comprising:
providing a first electrically conductive layer;
depositing an insulating layer above the first electrically conductive layer (12);
depositing a back contact metal layer above the insulating layer;
forming at least one first trench extending through the back contact metal layer, wherein each of the at least one first trenches separates the back contact metal layer for a respective CdTe PV cell from the back contact metal layer of a respective neighboring CdTe PV cell;
depositing a CdTe absorber layer at least partially above the back contact metal layer;
depositing a window layer above the CdTe absorber layer;
forming at least one second trench extending through the absorber and window layers, wherein each of the at least one second trenches separates the absorber and window layers for a respective CdTe PV cell from the absorber and window layers of a respective neighboring CdTe PV cell;
depositing a second electrically conductive layer at least partially above the window layer;
forming at least one third trench extending through the second electrically conductive layer, wherein each of the at least one third trenches separates the second electrically conductive layer for a respective CdTe PV cell from the second electrically conductive layer of a respective neighboring CdTe PV cell; and
depositing a high resistance transparent conductive oxide (HRT) layer after depositing the window layer and before depositing the second electrically conductive layer, wherein the steps of forming the second and third trenches are performed after the deposition of the HRT layer, such that the second and third trenches extend through the HRT layer.
